(19) United States
(12) Patent Application Publication
(10) Pub. No.: US 2006/0193969 A1
(43) Pub. Date: Aug. 31, 2006

(54) Method and apparatus for streaming a viscous material on a substrate

(75) Inventors: Thomas C. Prentice, Westford, MA (US); Brian P. Prescott, Fremont, NH (US); Kenneth C. Crouch, N. Andover, MA (US); Gerald C. Pham-Van-Diep, Hopkinton, MA (US)

Correspondence Address: LOWRIE, LANDO & ANASTASI, RIVERFRONT OFFICE, ONE MAIN STREET, ELEVENTH FLOOR, CAMBRIDGE, MA, 02142, US

(73) Assignee: Speedline Technologies, Inc., Franklin, MA (US)

(21) Appl. No.: 11/065,761

(22) Filed: Feb. 25, 2005

(51) Int. Cl. C23C 16/52

(52) U.S. Cl. 427/8; 118/683; 118/323

(57) ABSTRACT

A method for streaming a viscous material onto an electronic substrate using a dispensing system having a dispenser includes positioning a nozzle of the dispenser at a nominal clearance height above the substrate, dispensing a continuous stream of viscous material from the nozzle to dispense an amount of material on the substrate, controlling the volumetric flow rate of the viscous material being dispensed by the dispenser, moving the nozzle over areas of the substrate requiring viscous material, and terminating the continuous stream of viscous material. A dispensing system for performing methods of streaming viscous material is further disclosed.

### BACKGROUND OF THE INVENTION

1. Field of the Invention

The present invention relates generally to methods and apparatus for dispensing a viscous material on a substrate, such as a printed circuit board, and more particularly to a method and an apparatus for dispensing a continuous stream of material on a substrate.

2. Discussion of Related Art

There are several types of prior art dispensing systems used for dispensing metered amounts of liquid or paste for a variety of applications. One such application is the assembly of integrated circuit chips and other electronic components onto circuit board substrates. In this application, automated dispensing systems are used for dispensing dots of liquid epoxy or solder paste, or some other related material, onto circuit boards. Automated dispensing systems are also used for dispensing lines of underfill materials and encapsulents, which mechanically secure components to the circuit board. Underfill materials and encapsulents are used to improve the mechanical and environmental characteristics of the assembly.

Another application is to dispense very small amounts or dots onto a circuit board. In one system capable of dispensing dots of material, a dispensing pump utilizes a rotating auger having a helical groove to force material out of a nozzle and onto a circuit board. One such system is disclosed in U.S. Pat. No. 5,819,983, entitled LIQUID DISPENSING SYSTEM WITH SEALING AUGERING SCREW AND METHOD FOR DISPENSING, which is owned by Speedline Technologies, Inc. of Franklin, Mass., the assignee of the present invention.

In a typical operation employing an auger-type dispenser, the dispensing pump is lowered towards the surface of the circuit board prior to dispensing a dot or a line of material onto the circuit board and raised after dispensing the dot or line of material. Using this type of dispenser, small, precise quantities of material may be placed with great accuracy. The time required to lower and raise the dispensing pump in a direction normal to the circuit board, typically known as a z-axis movement, can contribute to the time required to perform dispensing operations.

It is also known in the field of automated dispensers to use “jetting” to launch dots of viscous material toward the circuit board. In such a jetting system, a minute, discrete quantity of viscous material is ejected from a nozzle with sufficient inertia to enable the material to separate from the nozzle prior to contacting the circuit board. With the auger-type application or other prior, non-jetting systems, it is necessary to wet the circuit board with the dot of material prior to releasing the dot from the nozzle. With jetting, the dots may be deposited on the substrate without wetting as a pattern of discrete dots, or alternatively the dots may be placed sufficiently close to each other to cause them to coalesce into more or less a continuous pattern. One such prior art jetting system is disclosed in U.S. Pat. No. 5,320,250, entitled METHOD FOR RAPID DISPENSING OF MINUTE QUANTITIES OF VISCOUS MATERIAL.

One advantage associated with known jetting systems is their relative insensitivity to variations in the distance from the nozzle to the circuit board when dispensing occurs. In most instances, the nozzle is capable of dispensing multiple dots toward the circuit board without having to perform z-axis movements toward or away from the circuit board. However, a significant disadvantage of jetting systems is their limited ability to dispense only small dots of material, each having a fixed size. If larger dots are required, typical jetting systems can dispense multiple, individual dots at the same location, thereby collectively contributing sufficient material to create the larger dot. Alternatively, the jetting system may be reconfigured to use a larger nozzle, thereby enabling a larger dot. If a smaller dot is required, the jetting system may be configured to use a smaller nozzle. Reconfiguring the nozzle is an undesirable option since the dispenser must typically be shut down, which negatively impacts the throughput of a line in which the dispenser operates.

Also, in typical jetting systems, the amount of material deposited must be an integer of the amount of material of a single dot, since, as described above, typical jetting systems are incapable, without significant modification, of changing the size of the dot. This limitation is typically due to the fixed size of the orifice of the nozzle that defines the size of the dot.

Another disadvantage associated with jetting systems is their limited ability to dispense lines of viscous material. As previously described, dots of material may be placed sufficiently close to each other to cause them to coalesce into a more or less continuous pattern. However, at each dot-to-dot interface, there exists the possibility of air entrapment. Furthermore, the same limitations on integer dot size exist with lines, especially since any line must be formed by an integer number of individual dots.

Jetting-type dispensing systems that have variable dispensed quantity size are known. However, one disadvantage associated with these systems is their difficulty in controlling the flow of viscous material through the nozzle. Specifically, the pressure of the viscous material at the inlet of the nozzle, or preceding a shut-off valve, is typically held relatively constant. Variations in the viscosity of the material to be dispensed and variations due to temperature changes or material aging, for example, will cause unwanted variations in the output flow rate resulting in an uncontrolled quantity of material to be dispensed.

### SUMMARY OF THE INVENTION

At least one aspect of the invention is directed to a method for streaming a viscous material onto an electronic substrate using a dispensing system having a dispenser. The method comprises positioning a nozzle of the dispenser at a nominal clearance height above the substrate; dispensing a continuous stream of viscous material from the nozzle to dispense an amount of material on the substrate; controlling the volumetric flow rate of the viscous material being dispensed by the dispenser; moving the nozzle over areas of the substrate requiring viscous material; and terminating the continuous stream of viscous material.

In an embodiment of the invention, the method further comprises measuring an amount of material dispensed on the substrate. The step of controlling the volumetric flow rate includes calculating an amount of material dispensed from the nozzle. The method further comprises comparing a calculated amount of material dispensed to a measured amount to determine the accuracy of material dispensed. The step of measuring the amount of viscous material dispensed on the substrate includes measuring a height and a width of dispensed material. The method further comprises controlling a speed at which the nozzle is moved over the substrate. The step of positioning a nozzle includes measuring a distance between the nozzle and the substrate by employing a non-contact optical sensor to measure the distance.

A second aspect of the invention is directed to a method of dispensing material onto an electronic substrate using a dispensing system, the method comprising: loading a substrate into the dispensing system, the substrate having a top surface onto which material is to be dispensed; positioning a nozzle of the dispensing system at a nominal clearance height above the substrate; dispensing a continuous stream of viscous material from the nozzle to dispense an amount of material on the substrate; moving the nozzle over areas of the substrate; controlling at least one of a volumetric flow rate of viscous material being dispensed and a speed at which the nozzle is moved over the substrate; and terminating the continuous stream of viscous material.

In an embodiment of the invention, the method further comprises measuring an amount of material dispensed on the substrate. The step of controlling the volumetric flow rate includes calculating an amount of material dispensed from the nozzle. The method further comprises comparing a calculated amount of material dispensed to a measured amount to determine the accuracy of material dispensed. The step of measuring the amount of viscous material dispensed on the substrate includes measuring a height and a width of dispensed material. The step of positioning a nozzle includes measuring a distance between the nozzle and the substrate by employing a non-contact optical sensor to measure the distance.

A third aspect of the invention is directed to a dispensing system for streaming a viscous material on a substrate. The dispensing system comprises a frame and a dispensing pump movably coupled to the frame. The dispensing pump includes a nozzle positioned at a nominal clearance height above the substrate to dispense viscous material on the substrate. A controller is coupled to the dispensing pump, the controller being adapted to control movement of the dispensing pump to dispense a continuous stream of viscous material over areas of the substrate requiring viscous material, and control a volumetric flow rate of the continuous stream of material being dispensed by the dispensing pump.

In an embodiment of the invention, the dispensing system further includes a measuring probe to measure a distance between the nozzle and the substrate. The dispensing system further includes an imaging inspection system to capture an image of the dispensed material so as to measure a height and width of dispensed material. The controller is adapted to control a speed at which the nozzle is moved over the substrate.

A fourth aspect of the invention is directed to a dispensing system for streaming a viscous material on a substrate, the dispensing system comprising a frame and a dispensing pump movably coupled to the frame. The dispensing pump includes a nozzle positioned at a nominal clearance height above the substrate to dispense viscous material on the substrate. The dispensing system further comprises means for controlling the movement of the dispensing pump to dispense a continuous stream of viscous material over areas of the substrate, and means for controlling a volumetric flow rate of the continuous stream of material being dispensed by the dispensing pump.

In an embodiment of the invention, the means for controlling the movement of the dispensing pump and the means for controlling the volumetric flow rate comprises a controller. The controller is adapted to control a speed at which the nozzle is moved over the substrate. The dispensing system further comprises a measuring probe to measure a distance between the nozzle and the substrate, and an imaging inspection system to capture an image of the dispensed material so as to measure a height and width of dispensed material.

The present invention will be more fully understood after a review of the following figures, detailed description and claims.

### BRIEF DESCRIPTION OF THE DRAWINGS

For a better understanding of the present invention, reference is made to the figures which are incorporated herein by reference and in which:

FIG. 1 is a schematic view of a dispensing system used with embodiments of the present invention;

FIG. 2 is a perspective view of a dispensing pump in accordance with an embodiment of the present invention;

FIG. 3 is an exploded view of a distribution block of the dispensing pump shown in FIG. 2;

FIG. 4 is a cross-sectional view of the dispensing pump shown in FIG. 2;

FIG. 5 is another cross-sectional view of the dispensing pump of FIG. 2;

FIG. 6 is a perspective view of a drive cam used in the dispensing pump of FIG. 2;

FIG. 7 is a flow chart of a method in accordance with an embodiment of the present invention;

FIG. 8 is a schematic view of a measuring system in accordance with an embodiment of the present invention; and

FIG. 9 is a schematic view of a vision system in accordance with an embodiment of the present invention.

### DETAILED DESCRIPTION OF THE PREFERRED EMBODIMENTS

For the purposes of illustration only, and not to limit the generality, the present invention will now be described in detail with reference to the accompanying figures. This invention is not limited in its application to the details of construction and the arrangement of components set forth in the following description or illustrated in the drawings. The invention is capable of other embodiments and of being practiced or being carried out in various ways. Also the phraseology and terminology used herein is for the purpose of description and should not be regarded as limiting. The use of “including,” “comprising,” “having,” “containing” “involving,” and variations thereof herein, is meant to encompass the items listed thereafter and equivalents thereof as well as additional items.

Embodiments of the present invention are directed to dispensing pumps, methods of dispensing and dispensing systems that contain methods and apparatus of the present invention. Embodiments of the present invention can be used with dispensing systems offered under the brand name CAMALOT® by Speedline Technologies, Inc. of Franklin, Mass., the assignee of the present invention.

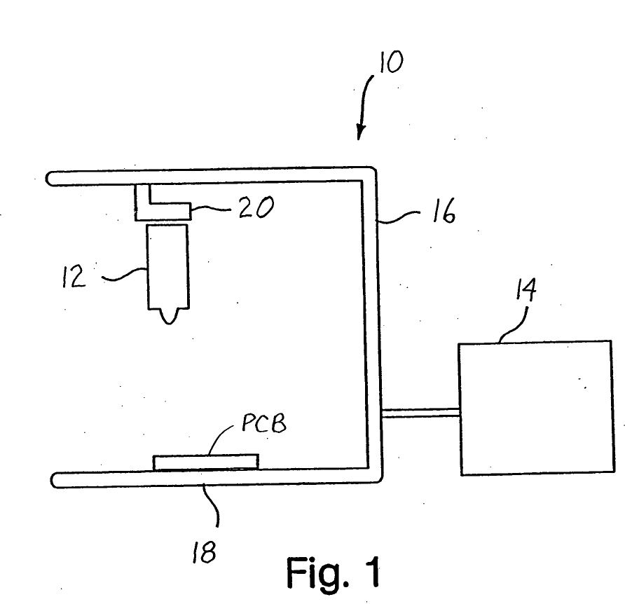

FIG. 1 illustrates a dispensing system (or dispenser) in accordance with one embodiment of the invention, generally indicated at 10, used to dispense a viscous material (e.g., adhesive, encapsulent, epoxy, solder paste, underfill material, etc.) or a semi-viscous material (e.g., soldering flux, etc.) onto a printed circuit board (PCB as shown in FIG. 1). The dispensing system 10 includes a dispensing pump 12 and a controller 14. The dispensing system 10 also includes a frame 16 having a base 18 for supporting the circuit board and an arm 20. As is well known in the art of printed circuit board fabrication, a conveyor system may be used in the dispensing system 10 to control loading and unloading of circuit boards to and from the dispensing system. The arm 20 is movably coupled to the dispensing pump 12 and is movably coupled to the frame 16. The arm 20 can be moved using motors under the control of the controller 14 in the x-axis, y-axis and z-axis directions to position the dispensing pump 12 at predetermined locations, and heights, if necessary, over the circuit board.

In one embodiment, as discussed below, the dispenser system is constructed to provide continuous dispensing with a controlled volumetric flow rate. In addition, in at least one embodiment, the dispenser 12 may be moved laterally across a circuit board, or other substrate, during dispensing. Further, in embodiments, the dispensing system is controlled to provide sufficient velocity to material being dispensed such that when dispensing is terminated material is ejected from the dispenser without the need to “wet” the circuit board as in prior art systems.

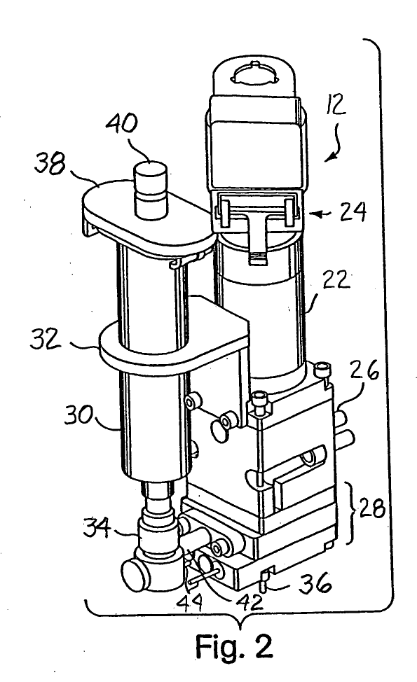

In one embodiment of the dispensing system 10 discussed above, the pump 12 may be implemented using a multi-piston pump, such as the pump disclosed in U.S. Pat. No. 6,514,569, entitled VARIABLE VOLUME POSITIVE DISPLACEMENT DISPENSING SYSTEM AND METHOD, which is incorporated herein by reference, and described herein below with reference to FIGS. 2-6. While it is desirable to use the pump 12 discussed below, embodiments of the present invention are not limited for use with the pump 12. The dispensing pump 12 has three pistons that move within three cylinders to draw material into the cylinders and cause material to be dispensed from the cylinders. As understood by individuals skilled in the art, the teachings of the present invention can be achieved by dispensing pumps having more or less than three cylinders.

The positive displacement dispensing pump 12 illustrated in FIG. 2 includes a servo motor 22, an encoder 24, a cylinder housing 26, a distribution block 28, a syringe 30, a syringe bracket 32, a syringe block 34, and a dispensing needle 36 (sometimes referred to as a nozzle). The dispensing pump 12 may be mounted on the dispensing system 10 using a bracket (not shown) that couples the servo motor 22 of the dispensing pump to the frame 16 of the dispensing system. The dispensing pump 12 provides controlled dispensing of viscous material (and semi-viscous material) contained in the syringe 30 out of the needle 36 and onto the circuit board. As will be described in greater detail below, a valve assembly is selectively positionable to dispense a continuous stream of material onto the circuit board during a dispensing operation.

The encoder 24 is designed to couple with the controller 14 to coordinate transfer of control signals between the controller and the servo motor 22 of the dispensing pump 12. The servo motor 22 may be implemented using one of a number of known motors. The servo motor 22 is the primary drive motor of the dispensing pump 12 and controls the movement of cylinders contained within the cylinder housing 26. The controller 14 controls the position of the servo motor 22 by moving the servo motor a fixed number of encoder positions in response to signals from the controller 14. As set forth above, the material is used to attach electrical components on the printed circuit board, and may include adhesives, encapsulents, epoxies, solder paste, underfill materials, and soldering fluxes.

The syringe 30 contains material to be dispensed by the dispensing pump 12. The syringe 30 is held in place using the syringe bracket 32 and the syringe block 34. The syringe 30 has a cap 38 that has a pressurized air inlet 40 for coupling a pressurized air source to apply pressure to the viscous material in the syringe. The syringe block 34 includes a material feed tube 42 to provide material flow between the syringe 30 and the inlet of the distribution block 28. For many applications, it may be desirable to control the temperature of the viscous material by employing cartridge heaters 44 to provide a consistent viscosity to improve the dispensing accuracy of the dispensing pump 12.

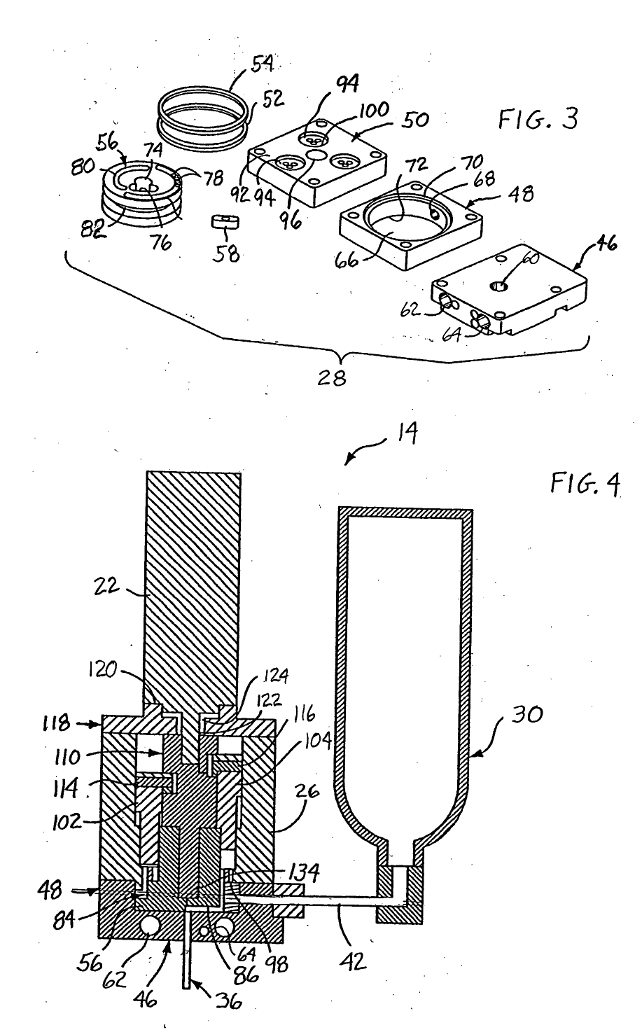

Turning to FIG. 3, the distribution block 28 includes a needle mating plate 46, a valve spacer plate 48, a cylinder base plate 50, a lower gasket 52, an upper gasket 54, a disk valve 56 and a key 58. The needle mating plate 46 includes a through hole 60 into which the needle 36 is mounted, and two cylindrical channels 62, 64 for receiving the cartridge heaters 44.

The valve spacer plate 48 mounts on top of the needle mating plate 46. The valve spacer plate 48 has a circular opening 66, a channel 68 and two annular grooves 70, 72. The circular opening 66 is provided for receiving the disk valve 56. The channel 68 is provided for passing dispensing material from the syringe 30 via the feed tube 42 to the disk valve 56. The lower gasket 52 and the upper gasket 54 fit into annular grooves 70, 72, respectively, to provide a seal between the disk valve 56 and the valve spacer plate 48. In one embodiment of the present invention, the lower gasket and the upper gasket are made from ethylene polypropylene to provide compatibility with commonly used cleaning solutions.

The disk valve 56 includes a center circular hole 74, a substantially oval-shaped hole 76, inlet holes 78, outlet holes 80, an annular groove 82, an inlet passage 84 and an outlet passage 86. The inlet passage 84 and the outlet passage 86 are shown in FIG. 4. The circular hole 74 extends approximately half way through the disk valve 56 and receives an end 88 of a drive cam 90. The oval-shaped hole 76 receives the key 58, which secures the drive cam 90 with respect to the disk valve 56 to provide rotational alignment between the drive cam and the disk valve and to allow the disk valve to rotate with the drive cam. The inlet holes 78 are coupled to the annular groove 82 to allow dispensing material to flow from the syringe 30 through the channel 68 of the valve spacer 48 into the annular groove and through the inlet holes. The outlet holes 80 are coupled to the outlet passage 86. The outlet passage 86 has an opening (not shown) on the center of the bottom surface of the disk valve 56 that couples to the dispensing needle 36. Dispensed material flows from the cylinders, as will be described below, through the outlet holes 80 and through the outlet passage 86 to the dispensing needle 36. In one embodiment of the present invention, the dispensing needle 36 is a 25-27 gauge needle, having a bore diameter between 0.007 and 0.009 inch. The bore diameter of the dispensing needle 36 is dependent on the average particle size of the material being dispensed. Also, the size of the bore diameter effects the velocity of the material being streamed by the dispensing pump 12.

The cylinder base plate 50 has a substantially smooth bottom surface that mates with the top surface of the valve spacer plate 48. A top surface 92 of the cylinder base plate 50 has three circular indentations that form a cylinder base 94 for each of the cylinders of the dispensing pump 12. The cylinder base plate 50 also includes a cylindrical channel 96 that allows the end of the drive cam 90 to pass through the cylinder base plate to mate with the disk valve 56. Each of the cylinder bases 94 has two inlet holes 98 and one outlet hole 100. In other embodiments of the present invention, the two inlet holes 98 may be joined to form an inlet slot. The inlet holes 98 align with the inlet holes 78 of the disk valve 56 during rotation of the disk valve to allow material to flow into the cylinder. The outlet hole 100 aligns with the outlet holes 80 of the disk valve 56 to allow material to flow from the cylinder through the outlet holes. In other embodiments of the present invention, each of the cylinder base plates may be constructed with only one hole that functions as both an inlet hole and an outlet hole.

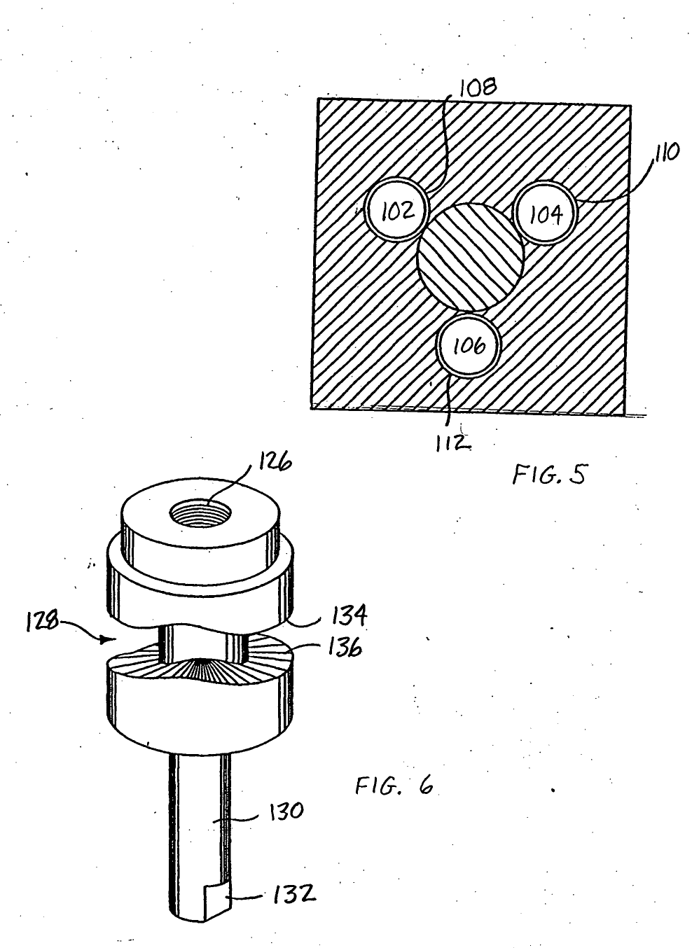

The cylinder housing 26 will now be described in greater detail with reference to FIGS. 4 and 5. The cylinder housing 26 includes three pistons 102, 104, 106, each piston being disposed in a cylinder 108, 110, 112. At the top of each of the pistons 102, 104, 106 is a cam follower 114, 116. Only two of the cam followers 114, 116 can be seen in the view illustrated in FIG. 4. In one embodiment, the pistons 102, 104, 106 are made from stainless steel and are press fit to the cam followers 114, 116. In one preferred embodiment of the present invention, the diameter of each cylinder 108, 110, 112 is 0.125 inch. The provision of relatively small diameter pistons increases the velocity of material streamed through the dispensing needle 36. Each of the pistons 102, 104, 106 is substantially identical in construction, and is coupled to one of the cam followers 114, 116. The cylinder housing 26 also includes the drive cam 90 and a motor mating plate 118. The motor mating plate 118 provides a surface 120 on which the servo motor 22 mounts, and the motor mating plate provides an opening 122 through which a drive shaft 124 of the motor extends.

The drive cam 90 is shown in greater detail in FIG. 6. The drive cam 90 has a threaded cylindrical channel 126, an annular groove 128, and a shaft 130. The cylindrical channel 126 receives the drive shaft 124 to provide rotation of the drive cam 90 by the servo motor 22. The shaft 130 extends through the cylinder housing 26 and into the disk valve 56. An end 132 of the shaft 130 is designed to mate with the key 58. The rotation of the drive cam 90 causes the disk valve 56 to rotate so that at the appropriate times, the inlet holes 78 and the outlet holes 80 of the disk valve are aligned respectively with the inlet holes 98 and the outlet hole 100 of one of the cylinder bases 94 of the cylinder base plate 50. In one embodiment of the present invention, the drive cam 90, and thus, the disk valve 56 is rotated in a counterclockwise direction when viewed from the top of the dispensing pump 12 looking down in FIG. 5. However, in other embodiments, the pumps may be configured to drive the disk valve 56 in a clockwise direction.

The annular groove 128 has an upper surface 134 and a matching lower surface 136. The cam followers 114, 116 reside in the annular groove 128 between the upper surface 134 and the lower surface 136. The upper surface 134 and the lower surface 136 of the annular groove 128 are contoured to provide raising and lowering of the cam followers 114, 116 in the annular groove as the drive cam 90 is rotated by the servo motor 22. The movement of the cam followers 114, 116 in the annular groove 128 causes the pistons 102, 104, 106 to be raised and lowered to draw material into the pump 12 and dispense material from the pump. In one embodiment of the present invention, the annular groove 128 is designed to provide a 0.250 inch stroke for the piston (102, 103, 104), such that the piston moves 0.250 inches from its retracted position to its extended position. In addition, the annular groove 128 has flat sections that result in dwell periods of the pistons. The dwell periods are timed to coincide with the opening and closing of the valves of the disk valve 56 to prevent vertical movement of the pistons while the valves are opened and closed.

The dispensing pump 12 illustrated in FIGS. 2-6 is controlled in embodiments of the invention to generate a continuous stream of viscous material. The pistons 102, 104, 106 are timed with respect to one another to ensure that a continuous stream of material is dispensed when the controller 14 calls for a dispensing operation. Specifically, at the start of a dispensing operation, air pressure is provided to the viscous material in the syringe 30 through the air inlet 40 to move viscous material from the syringe to the cylinders 108, 110, 112. The pistons 102, 104, 106 are timed so that as a piston in one cylinder is dispensing material from the syringe 30, the pistons in the other cylinders are in the process of preparing for a dispensing stroke. Thus, the dispensing system 10 and dispensing pump 12 illustrated in FIGS. 1 and 2, respectively, are particularly adapted to continuously stream material, whether viscous material (e.g., adhesives, encapsulents, epoxies, solder paste, underfills, etc.) or semi-viscous material (e.g., soldering flux, etc.), so that the dispensing pump can quickly and efficiently apply material to a predetermined area. In addition, in embodiments, the dispensing pump 12 is controlled such that a precise amount of material is dispensed during a continuous dispensing operation by controlling the positive displacement of the pistons 102, 104, 106 within the cylinders 108, 110, 112. Still further, the dispensing pump is controlled by the controller to apply sufficient inertia to the material, so that when the dispensing is terminated, a continuous stream of material breaks free from the needle.

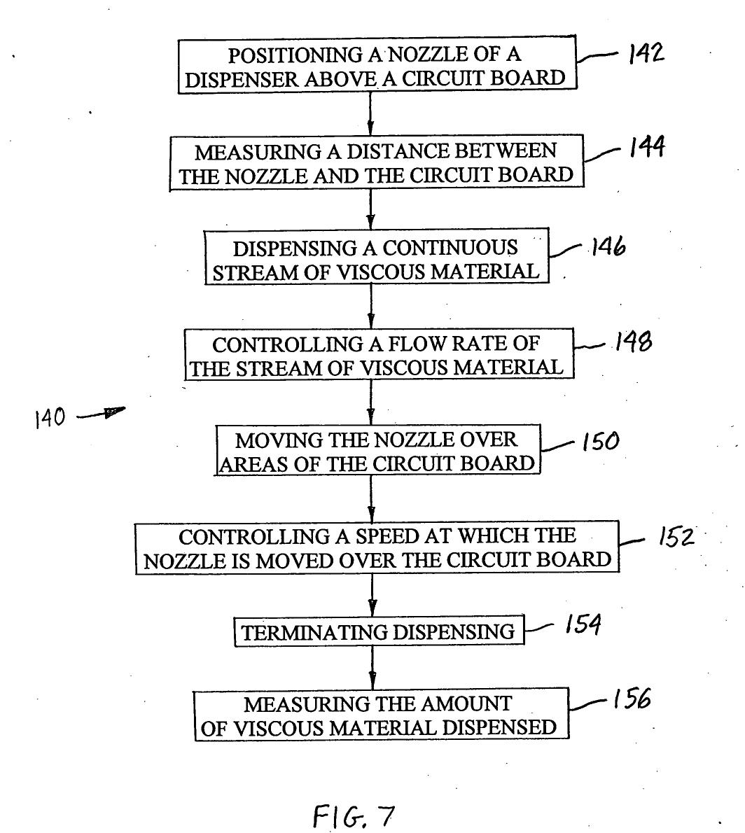

Turning now to FIG. 7, there is illustrated a method, generally indicated at 140, that may be implemented using system 10 for streaming viscous material on a substrate in accordance with one embodiment of the present invention. As shown, the method 140 comprises: (a) positioning and maintaining the nozzle of the dispenser above the circuit board (shown in stage 142); (b) measuring a distance between the nozzle and the circuit board (shown in stage 144) and correcting the height of the nozzle, if required; (c) dispensing a continuous stream of viscous material (shown in stage 146); (d) controlling a flow rate of the stream of viscous material (shown in stage 148); (e) moving the nozzle over areas of the circuit board (shown in stage 150); (f) controlling a speed at which the nozzle is moved over the circuit board (shown in stage 152); (g) terminating dispensing of the viscous material (shown in stage 154); and (h) measuring the amount of viscous material dispensed (shown in stage 156). It should be understood that not all of the foregoing stages are necessary to practice methods of the present invention, and the stages need not be performed in the sequence set forth above. For example, a method comprising: (a) positioning and maintaining the nozzle at a nominal clearance height above the circuit board; (b) dispensing a continuous stream of viscous material from the nozzle on the circuit board; (c) controlling the volumetric flow rate of material being dispensed; (d) moving the nozzle over areas of the circuit board requiring viscous material; and (e) terminating the continuous stream of material, is contemplated herein. In addition, further contemplated is a method of dispensing material using a dispensing system, such as dispenser 10, comprises: (a) loading a circuit board into the dispensing system; (b) positioning and maintaining the nozzle at a nominal clearance height above the circuit board; (c) dispensing a continuous stream of material from the nozzle on the circuit board; (d) moving the nozzle over areas of the circuit board requiring material; (e) controlling one of (i) a volumetric flow rate of material being dispensed, and (ii) a speed at which the nozzle is moved; and (f) terminating the stream of material. The foregoing alternative methods are for illustration purposes only, and are not intended to be limiting.

In operation, the dispensing pump (e.g., dispensing pump 12) is positioned at a nominal clearance height above the circuit board. This clearance height is maintained at a relatively consistent elevation above the circuit board throughout the dispense operation, although variations in the height of the circuit board, or irregularities in the flatness of the top surface of the circuit board, may cause the clearance height to vary without adversely impacting the streaming of viscous material. Specifically, the dispensing pump does not need to lift the nozzle away from the circuit board in the z-axis direction at the end of each dispense operation. However, to accommodate variations in the height of the circuit board and irregularities in the flatness of the circuit board (or to even avoid obstacles), the dispenser may be configured to achieve z-axis movement.

During a dispense operation, material dispensed from the nozzle streams from the nozzle in such a manner that material may touch the nozzle and the circuit board simultaneously at times during the dispense operation between the start of dispensing and the end of dispensing. In one embodiment, the nozzle of the dispensing pump operates at a height above the circuit board, e.g., at approximately 0.010 inch to approximately 0.040 inch, to perform the streaming of viscous material described herein.

In one embodiment of the present invention, to achieve the object of maintaining the height of the nozzle of the dispensing pump at a desired elevation above the circuit board, there is provided a system for measuring the height of the dispenser nozzle above the circuit board in the z-axis direction. In some height (or distance) measuring systems, physical contact is made between the measuring system and the surface (e.g., a surface of a substrate embodying a printed circuit board) to be measured. One such height measuring system is described in U.S. Pat. No. 6,093,251, entitled APPARATUS FOR MEASURING THE HEIGHT OF A SUBSTRATE IN A DISPENSING SYSTEM, which is assigned to the assignee of the present invention, and is incorporated herein by reference. Specifically, U.S. Pat. No. 6,093,251 discloses a measuring probe that is extendable between a reference point and a location on the circuit board to measure the height of the substrate. FIG. 8 illustrates a dispensing system 10 having a measuring probe 160 used to measure the distance between the dispensing needle 36 of the dispensing pump 12 and the circuit board.

In other height measuring systems, a laser light source and an optical sensing system are combined to measure the position of an object without making physical contact. An example of a non-contact measuring system is manufactured and distributed by Micro-Epsilon Messtechnik GmbH of Ortenburg, Germany. With reference to FIG. 8, the optical sensing system can replace the measuring probe 160. In other embodiments of the present invention, the height measuring system can be incorporated to facilitate the measurement of and compensation for variations in the vertical position of the top surface of the circuit board.

Using height measuring systems described above, systems of the invention are capable of measuring the distance or height of the tip of the nozzle (e.g., dispensing needle 36) above the top surface of the circuit board. Maintaining the height of the nozzle above the substrate is one factor to control in an effort to optimize the continuous streaming of material. Specifically, the height of the nozzle above the circuit board must be sufficient to ensure the continuous dispensing of material out of the nozzle without risk of the nozzle touching the circuit board. Also, the height of the nozzle, if too high above the circuit board, may cause the material to splash on the circuit board and cause undesirable satellites.

Once the height of the nozzle above the top surface of the circuit board is determined and corrected, if required, the dispensing pump 12 may be engaged to dispense the continuous stream of viscous material. A predetermined dispense operation may be programmed into the controller of the dispensing system 10, which may form a part of a line of equipment used to surface mount components onto a printed circuit board. Specifically, an area of the top surface of the circuit board requiring viscous material is preprogrammed into the controller. The quickness at which material is dispensed by the dispensing system 10 is controlled by manipulating the volumetric flow rate of the stream of viscous material and the speed at which the nozzle is moved over the circuit board. The speed at which the motor (e.g., the servo motor 22) operates and the viscosity of the material being dispensed are factors used to determine an optimal volumetric flow rate. Given the continuous streaming of material and the lack of z-axis directional movement of the nozzle over the circuit board, the material is capable of being dispensed quickly and efficiently to cover the predetermined area.

During dispensing, the continuous stream of material is initiated, and lateral motion (i.e., x-axis and y-axis) of the dispensing system is commenced, either prior to or after the initiation of the dispense operation, depending on the volumetric flow rate and the viscosity of the material. The flow rate of material must be sufficient to overcome the surface tension of the material within the nozzle (e.g., the dispensing needle 36). Once the area is covered with the desired amount of material, the dispensing operation is terminated. The dispensing system 10 ejects material from the dispensing needle 36 with sufficient inertia so that when the dispensing system ceases the flow of material, the continuous stream of material breaks free from the needle. Thus, it may be necessary to continue moving the dispensing pump 12 even after dispensing of material has terminated to stream material that is located between the disk valve 56 and the dispensing needle 12. As described above, by varying the volumetric flow rate at which the material is dispensed, the velocity of the material as it exits the needle and thus the velocity at which it impacts the circuit board can be controlled by the controller. If too low a volumetric flow rate is used, the exit velocity, and therefore the exit inertia, is insufficient to enable the stream of material to clearly detach from the nozzle. If too high a volumetric flow rate is used, then the stream of material impacts the circuit board at too high a velocity which may cause undesirable splashing of material and satellites. Furthermore, by varying the speed at which the dispensing material is moved over the circuit board in the x-axis and the y-axis directions, the effective width of the line of material is additionally controlled.

In order to produce a dispensed line of uniform width and cross section, embodiments of the present invention may initiate the lateral motion of the dispensing pump relative to the circuit board prior to the start of material delivery. Likewise, to maintain the uniformity of the dispensed line at the termination of the dispensed pattern, the lateral motion of the dispensing pump may continue after material delivery is terminated. Depending on material characteristics and the particular nature of the application, such lateral motion before and after dispensing may improve the resultant dispensed pattern.

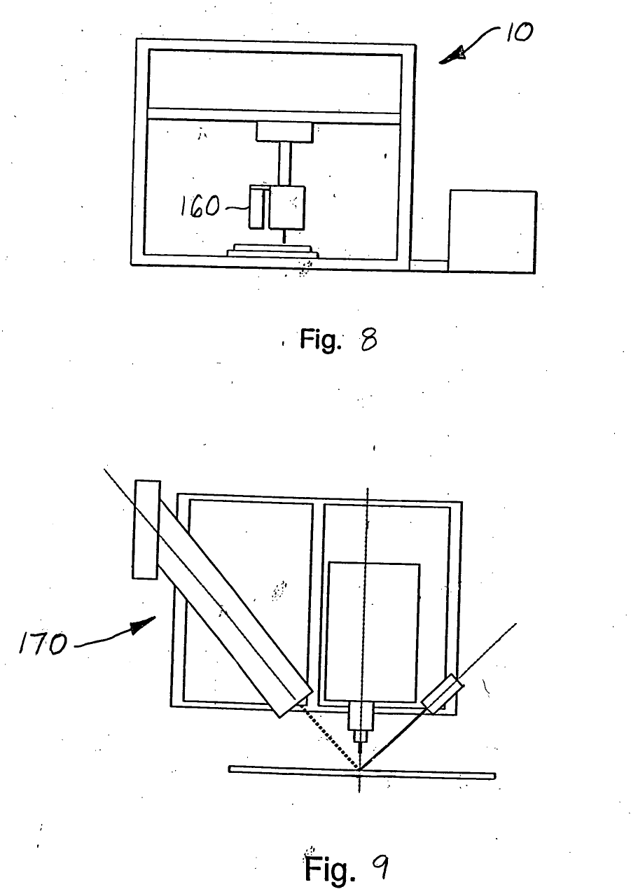

Referring now to FIG. 9, the stage of measuring (i.e., stage 156 in FIG. 7) the amount of viscous material dispensed can be achieved by monitoring the volumetric flow rate of material dispensed during a dispensing operation. In accordance with one embodiment of the present invention, the measurement is achieved by measuring the size of the deposited material. Specifically, the height and width of material dispensed onto the circuit board is measured by use of an off-axis imaging system, generally indicated at 170. Such a system 170 is disclosed in U.S. patent application Ser. No. 10/831,468, entitled IMAGING AND INSPECTION SYSTEM FOR A DISPENSER AND METHOD FOR SAME, which is assigned to the assignee of the present invention and incorporated herein by reference. The vision system 170 is positionable to obtain images of the top surface of the circuit board along an optical axis to capture the image. Specifically, the system 170 determines the characteristics of the dispensed material (e.g., the dispensed material's height and width). The characteristics of the dispensed material are compared with acceptable limits programmed into the controller and a determination is made as to whether the circuit board passes inspection or must be re-worked. The information derived from such an imaging system 170 is then used to adjust certain parameters of the dispensing process to more accurately achieve a desired result.

Once measured, the measured amount can be compared to a calculated amount of material dispensed to determine the accuracy of the dispensing operation. Specifically, the volumetric flow rate of the material being dispensed through the dispensing needle 36 can be calculated to establish a calculated amount. A flow meter may also be employed to calculate the amount of material being dispensed through the dispensing needle 36. The stage of capturing an image to establish a measured amount, although not required, helps improve the accuracy of the dispensing operation since any differential between the measured amount and the calculated amount can be corrected by the controller.

Thus, it should be observed that dispensing systems of at least one embodiment of the present invention are capable of continuous streaming of viscous material while controlling the volumetric flow rate of viscous material, all without wetting the circuit board. Prior art dispensers (whether traditional dispensers or jetting-type dispensers) are incapable of achieving these three objectives, i.e., (1) continuous streaming, (2) controlling the volumetric flow rate, and (3) non-wetting. Traditional dispensing (e.g., with the auger-type dispensers), while being capable of continuous streaming and of controlling the volumetric flow rate, typically wet the circuit board prior to dispensing. Typical jetting systems, while not requiring wetting, are typically incapable of continuous streaming and of controlling the volumetric flow rate. Lastly, with known jetting systems that are capable of dispensing material having variable quantity sizes, there is no way to control or measure the volumetric flow rate of material being dispensed.

Having thus described at least one embodiment of the present invention, various alternations, modifications and improvements will readily occur to those skilled in the art. Such alterations, modifications and improvements are intended to be within the scope and spirit of the invention. Accordingly, the foregoing description is by way of example only and is not intended to be limiting. The invention's limit is defined only in the following claims and equivalents thereto.

What is claimed is:

1. A method for streaming a viscous material onto an electronic substrate using a dispensing system having a dispenser, the method comprising:
positioning a nozzle of the dispenser at a nominal clearance height above the substrate;
dispensing a continuous stream of viscous material from the nozzle to dispense an amount of material on the substrate;
controlling the volumetric flow rate of the viscous material being dispensed by the dispenser;
moving the nozzle over areas of the substrate requiring viscous material; and
terminating the continuous stream of viscous material.

2. The method of claim 1, further comprising measuring an amount of material dispensed on the substrate.

3. The method of claim 2, wherein controlling the volumetric flow rate comprises calculating an amount of material dispensed from the nozzle.

4. The method of claim 3, further comprising comparing a calculated amount of material dispensed to a measured amount to determine the accuracy of material dispensed.

5. The method of claim 2, wherein measuring the amount of viscous material dispensed on the substrate comprises measuring a height and a width of dispensed material.

6. The method of claim 1, further comprising controlling a speed at which the nozzle is moved over the substrate.

7. The method of claim 1, wherein positioning a nozzle comprises measuring a distance between the nozzle and the substrate.

8. The method of claim 7, wherein measuring a distance comprises employing a non-contact optical sensor to measure the distance.

9. A method of dispensing material onto an electronic substrate using a dispensing system, the method comprising:
loading a substrate into the dispensing system, the substrate having a top surface onto which material is to be dispensed;
positioning a nozzle of the dispensing system at a nominal clearance height above the substrate;
dispensing a continuous stream of viscous material from the nozzle to dispense an amount of material on the substrate;
moving the nozzle over areas of the substrate;
controlling at least one of a volumetric flow rate of viscous material being dispensed and a speed at which the nozzle is moved over the substrate; and
terminating the continuous stream of viscous material.

10. The method of claim 9, further comprising measuring an amount of material dispensed on the substrate.

11. The method of claim 10, wherein controlling the volumetric flow rate comprises calculating an amount of material dispensed from the nozzle.

12. The method of claim 11, further comprising comparing a calculated amount of material dispensed to a measured amount to determine the accuracy of material dispensed.

13. The method of claim 10, wherein measuring the amount of viscous material dispensed on the substrate comprises measuring a height and a width of dispensed material.

14. The method of claim 9, wherein positioning a nozzle comprises measuring a distance between the nozzle and the substrate.

15. The method of claim 14, wherein measuring a distance comprises employing a non-contact optical sensor to measure the distance.

16. A dispensing system for streaming a viscous material on a substrate, the dispensing system comprising:
a frame;
a dispensing pump movably coupled to the frame, the dispensing pump including a nozzle positioned at a nominal clearance height above the substrate to dispense viscous material on the substrate; and
a controller coupled to the dispensing pump, the controller being adapted to control movement of the dispensing pump to dispense a continuous stream of viscous material over areas of the substrate requiring viscous material, and control a volumetric flow rate of the continuous stream of material being dispensed by the dispensing pump.

17. The dispensing system of claim 16, further comprising a measuring probe to measure a distance between the nozzle and the substrate.

18. The dispensing system of claim 16, further comprising an imaging inspection system to capture an image of the dispensed material so as to measure a height and width of dispensed material.

19. The dispensing system of claim 16, wherein the controller is adapted to control a speed at which the nozzle is moved over the substrate.

20. A dispensing system for streaming a viscous material on a substrate, the dispensing system comprising:
a frame;
a dispensing pump movably coupled to the frame, the dispensing pump including a nozzle positioned at a nominal clearance height above the substrate to dispense viscous material on the substrate;
means for controlling the movement of the dispensing pump to dispense a continuous stream of viscous material over areas of the substrate; and
means for controlling a volumetric flow rate of the continuous stream of material being dispensed by the dispensing pump.

21. The dispensing system of claim 20, wherein said means for controlling the movement of the dispensing pump and said means for controlling the volumetric flow rate comprises a controller.

22. The dispensing system of claim 21, wherein the controller is adapted to control a speed at which the nozzle is moved over the substrate.

23. The dispensing system of claim 20, further comprising a measuring probe to measure a distance between the nozzle and the substrate.

24. The dispensing system of claim 20, further comprising an imaging inspection system to capture an image of the dispensed material so as to measure a height and width of dispensed material.
